(19) United States
(12) Patent Application Publication
(10) Pub. No.: US 2007/0274059 A1
(43) Pub. Date: Nov. 29, 2007

(54) Apparatus and method for shielding of electromagnetic interference of a memory module

(76) Inventor: Siva (Chennupati)Raghuram, Germering (DE)

Correspondence Address: JENKINS, WILSON, TAYLOR & HUNT, P. A., 3100 TOWER BLVD., Suite 1200, DURHAM, NC, 27707, US

(21) Appl. No.: 11/440,880

(22) Filed: May 25, 2006

(51) Int. Cl. H05K 9/00

(52) U.S. Cl. 361/818

(57) ABSTRACT

An apparatus for shielding of electromagnetic interference of a memory module comprises a heat spreader covering at least partially said memory module, wherein said heat spreader is connected to at least one floating gate which is provided between first plates of matched integrated capacitors, wherein second plates of said matched integrated capacitors each comprise a constant potential.

### BACKGROUND OF THE INVENTION

The invention relates in general to an apparatus and a method for shielding of electromagnetic interference of memory modules and, in particular, to shielding of dual in-line memory modules (DIMM).

Memory modules are provided for increasing the memory capacity of a computer system. Originally, single in-line memory modules (SIMM) were used in personal computers to increase the memory size. A single in-line memory module comprises DRAM-memory chips on its printed circuit board (PCB) only on one side. The contacts for connecting the printed circuit board of the single in-line memory module (SIMM) are redundant on both sides of the module. A first variant of SIMS has 30 pins and provides 16 bits of data. A second variant of SIMMs which are called PS/2 comprises 72 pins and provides 32 bits of data.

Dual in-line memory modules (DIMM) have replaced the single in-line memory modules as the predominant type of memory modules. Since single in-line memory modules SIMS have memory units of DRAM-chips mounted on only one side of the printed circuit board (PCB), a dual in-line memory module comprises memory units mounted on both sides of the printed circuit board of the module.

A conventional dual in-line memory module (DIMM) has DRAM-memory chips on both sides of its printed circuit board. The dual in-line memory module (DIMM) can be connected to a main printed circuit board or mother board. Since memory requirements in a computer system are increasing day by day, i.e. both in terms of memory size and memory speed, it is desired to place a maximum number of memory chips (DRAMs) on each side of the dual in-line memory module (DIMM). With the increasing frequency and the increasing number of memory modules, the heat generated by the memory module is also increasing. A further problem is that, by increasing the operation frequency of the memory chips on the memory module, the memory module becomes on one hand more receptive to electromagnetic noise injection, and on the other hand transmits electromagnetic signals which might affect negatively other devices in the surrounding of the dual in-line memory module. Accordingly, the electromagnetic compatibility of a memory module is diminished with increasing operation frequencies.

### BRIEF SUMMARY OF THE INVENTION

The present invention provides an apparatus for shielding of electromagnetic interference of a memory module comprising a heat spreader enclosing at least partially said memory module,

wherein said heat spreader is connected to at least one floating gate which is provided between first plates of matched integrated capacitors, wherein second plates of said matched integrated capacitors each have a constant potential.

The invention further provides a memory module comprising a heat spreader surrounding enclosing a printed circuit board on which memory chips are mounted, wherein said heat spreader is connected to a floating gate of at least one integrated component having matched capacitors,

wherein said floating gate is provided between first plates of said matched capacitors and second plates of said matched capacitors, wherein each second plate of said matched capacitors has a constant potential.

The invention further provides a method for a shielding of electromagnetic interference of a memory module, wherein a noise current induced in a heat spreader surrounding said memory module is connected to at least one floating gate provided between first plates of matched capacitors, wherein to each second plate of said matched capacitors a constant voltage is applied.

An electromagnetic shielding of a memory module comprising a housing enclosing at least partially said memory module, and at least one integrated component connected to said housing said integrated component having at least one floating gate which is provided between first plates of matched capacitors integrated in said integrated component and having second plates to which a constant voltage is applied.

In the following, preferred embodiments of the apparatus and the method according to the present invention are described with reference to the is enclosed figures.

### BRIEF DESCRIPTION OF THE SEVERAL VIEWS OF THE DRAWINGS

FIG. 1 shows a sectional view of a dual in-line memory module according to the present invention.

FIG. 2 shows a view on a dual in-line memory module from above.

FIG. 3 shows a sectional view of a dual in-line memory module according to the present invention with an integrated component according to a preferred embodiment of the present invention.

FIG. 4 shows diagrams to illustrate the heat spreading by means of the heat spreader in a memory module according to the present invention.

FIG. 5 shows a perspective view of a heat spreader which can be clipped to a memory module according to the present invention.

### DETAILED DESCRIPTION OF THE INVENTION

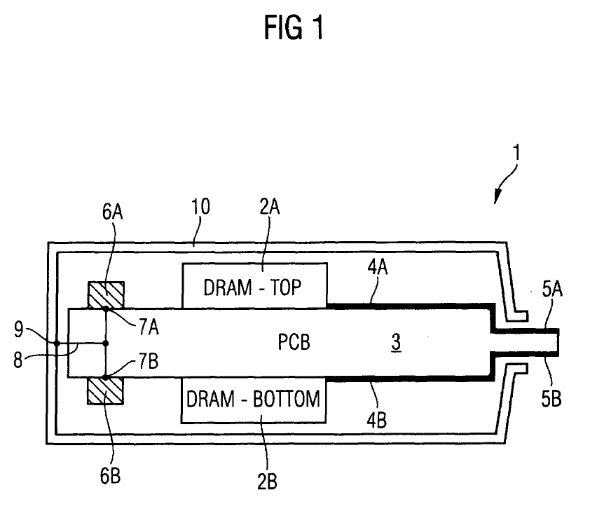

As can be seen from FIG. 1, a memory module 1 is in one embodiment of the apparatus according to the present invention formed by a dual in-line memory module having memory chips 2A, 2B mounted on both sides of a printed circuit board 3. The memory chips 2A, 2B are in a preferred embodiment DRAM-memory chips for storing data. There are provided DRAM-chips 2A on the top side of the dual in-line memory module 1 and DRAM-chips 2B on the bottom side of the dual in-line memory module 1. The memory chips 2A, 2B mounted on the printed circuit board 3 are connected via lines 4A, 4B to connection pads 5A, 5B. These connection pads 5A, 5B can be plugged into a main printed circuit board or mother board. Besides the memory chips 2A, 2B, at least one additional integrated component 6A, 6B is mounted on the printed circuit board 3 of the memory module 1. Each integrated component 6A, 6B comprises a floating gate 7A, 7B which is connected via a line 8 to a connection point 9 of a housing 10 formed by a heat spreader covering at least partially the memory module 1. The heat spreader 10 is formed by a material which is electrically and thermally conductive. The material is, for instance, copper aluminium, brass, iron or silver. In another embodiment, the heat spreader 10 is formed by carbon fibre. In a preferred embodiment, the heat spreader 10 almost completely surrounds the dual in-line memory module 1.

An advantage of the apparatus according to the present invention resides in that the heat generated by the memory module 1 is dissipated by the heat spreader 10 while reducing the electromagnetic interference by means of the heat spreader 10 at the same time. The heat spreader 10 spreads the heat on the dual in-line memory module 1 evenly. The heat spreader 10 is used further to shield electromagnetic interference, i.e. to reduce electromagnetic radiation transmitted from the memory module 1 and to reduce radiation from other devices affecting the memory module 1. The heat spreader 10 is not only used for spreading the heat evenly on the memory module 1, but also for reduction of electromagnetic interference.

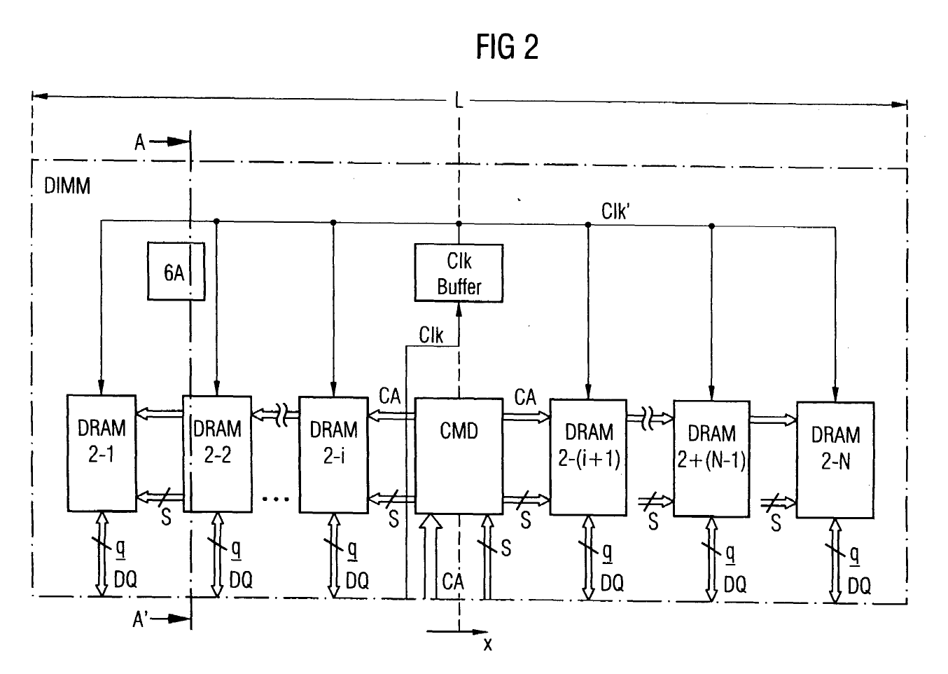

FIG. 2 shows an embodiment of a dual in-line memory module 1 from above with the heat spreader 10 being removed. The dual in-line memory module 1 comprises N DRAM-memory chips 2. Each memory chip 2 can comprise several stacked DRAM-memory dies. The dual in-line memory module 1 comprises one central command and address buffer CMD as shown in FIG. 2. The central command and address buffer CMD is located in the middle of the printed circuit board 3 of the dual in-line memory module 1. The command and address buffer CMD is connected via a command and address bus CA and a chip selection control bus 5 to all DRAM-memory chips 2 on the dual in-line memory module 1. The command and address buffer CMD receives command and address signals from a main circuit board and drives them via a command and address bus CA to all memory chips 2. The clock signals CLK′ for the memory chips 2 are spread from a clock buffer. The dual in-line memory module 1 comprises at least one contact pad which is connected via a clock line to the clock signal buffer. Further contact pads are provided for reading data DQ from the memory chips 2 or writing data into the memory chips 2 via data busses each having a bus width q. The external clock signal CLK received from the mother board is buffered by the clock signal buffer and applied to all memory chips 2 via an internal clock line CLK′.

The command and address buffer CMD in the middle of the dual in-line memory module 1 generates more heat than the memory chips 2 on the periphery of the dual in-line memory 1. The heat spreader 10 as shown in FIG. 2 spreads the heat evenly, i.e. to the periphery of the dual in-line memory module 1. As can be seen in FIGS. 1, 2, the dual in-line memory module 1 according to an embodiment of the present invention comprises on the upside of its printed circuit board 3 at least one integrated component 6A having a floating gate which is connected at a connection point 9 to the heat spreader 10.

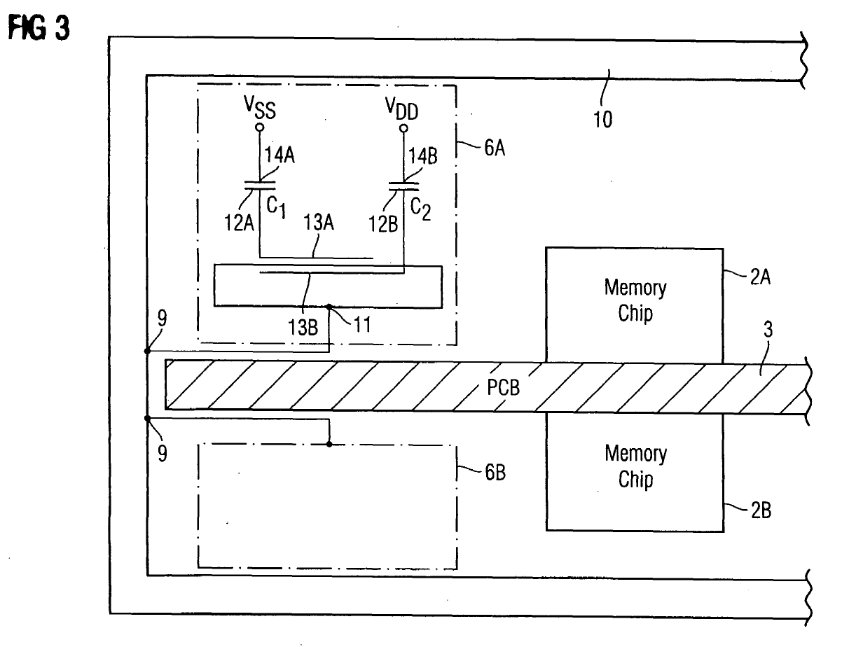

FIG. 3 shows the integrated component 6A in more detail. The integrated component 6A comprises a floating gate 11 which is provided between a first plate 13A, 13B of matched integrated capacitors 12A, 12B having second plates, 14A, 14B to which a constant potential is applied. The matched capacitors 12A, 12B have a matched, i.e. identical, capacity, and comprise the same behaviour in response to changes of the environment during the manufacturing process as well as during the operation of the memory module 1, such as changes of the temperature.

In the embodiment shown in FIG. 3, the second plate 14A of the first capacitor 12A is connected to a negative supply voltage VSS and the second plate 14B of the second integrated capacitor 12B is connected to a positive supply voltages VDD of the dual in-line memory module 1. The negative supply voltage VSS is, for example, formed by a ground GND-potential. The positive power supply voltage VDD is, e.g. 1,8 V. The integrated component 6A includes two integrated matched capacitors 12A, 12B. These balanced capacitors 12A, 12B are immune to temperature, voltage and aging performance differences. The integrated component 6A comprises almost no parasitic inductance. A noise current induced in the heat spreader 10 is suppressed quickly by the integrated component 6A. Electromagnetic radiation caused by the dual in-line memory module 1 itself leading to an induced noise current in the heat spreader 10 is also bypassed to the integrated component 6A. As shown in FIG. 3, an integrated component 6A, 6B may be mounted on one or on both sides of the printed circuit board 3. Furthermore, a point-to-point or a multiple point connection 9 to the heat spreader 10 is possible. Even when the memory module 1 works at a high operation frequency which may be up to some GHz, the generated electromagnetic waves which induce an electric current in the heat spreader 10 do not affect devices in the surrounding of the dual in-line memory module 1 because the induced noise currents are bypassed and conducted quickly to the integrated components 6A, 6B.

In the embodiment shown in FIG. 3, the integrated component 6A including the matched capacitors 12A, 12B forms a separate device mounted on the printed circuit board 3.

In an alternative embodiment, the integrated components 6A, 6B may be integrated into the memory chips 2A, 2B, respectively.

The integrated components 6A, 6B shown in FIG. 1 are provided because simple grounding of the heat spreader 10 is not effective. The ground potential of a dual in-line memory module 1 is always bouncing and can create noise which is also radiating. Furthermore, the ground potential might form a contact with a casing of the system in which the memory module is plugged thus forming inadmissable ground loops.

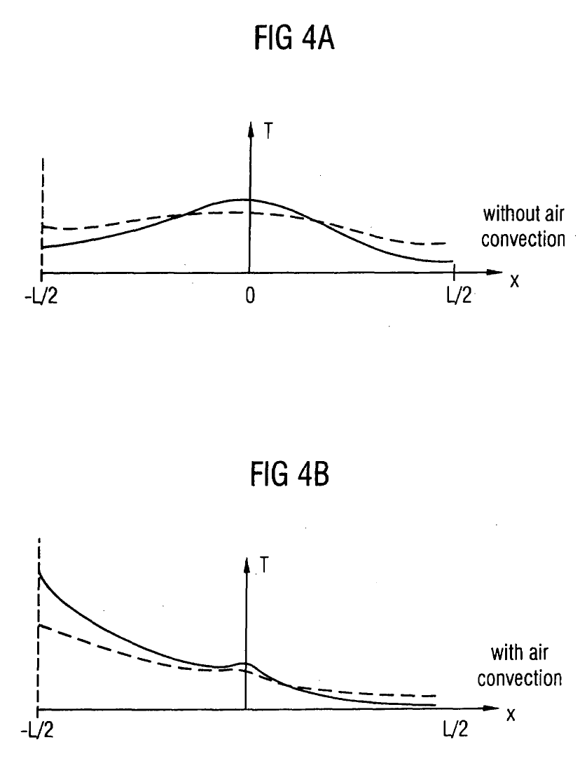

FIG. 4A shows a heat profile of a dual in-line memory module 1. The heat distribution has its maximum at the center of the dual in-line memory module 1. By use of the heat spreader 10, the heat is evenly distributed on the memory module as can be seen from the dashed line.

FIG. 4B shows the heat profile over a dual in-line memory module 1 supplied with additional air convection. As can be seen in FIG. 4B, the heat is asymmetrically distributed having a peak in the middle. On the side from where the air stream is coming, the temperature is lower than on the side which is turned away from the air convection stream.

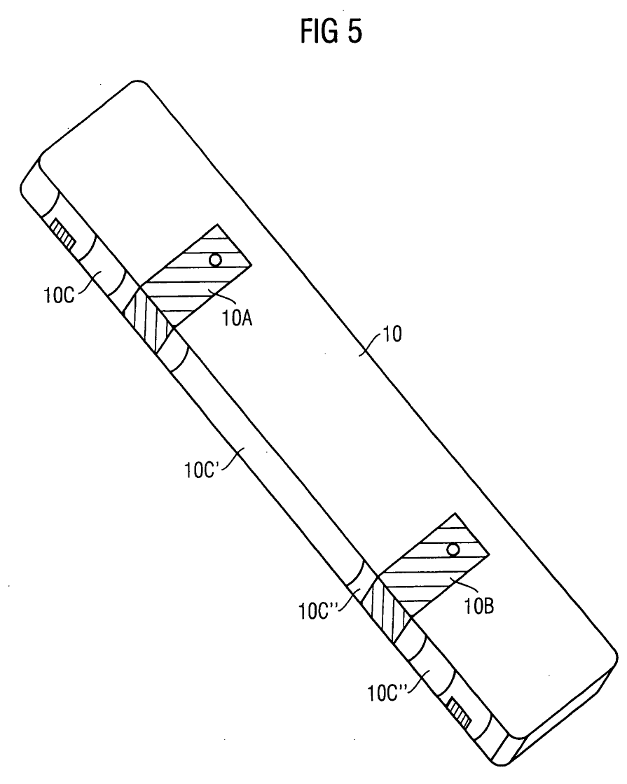

FIG. 6 shows an embodiment of the heat spreader 10 which covers at least partially the memory module 1. The heat spreader 10 almost completely surrounds at least one printed circuit board 3 of the memory module 1 on which the memory chips 2 are mounted. In a preferred embodiment, the heat spreader 10 comprises an upper heat spreader element and a bottom heat spreader element which are clipped together by clipping means 10A, 10B as shown in FIG. 5. The clipping means 10A, 10B are, for instance, made of metal. The rear side of the heat spreader 10 comprises openings 10C, 10C′, 10C″ through which contact pads of the memory module 1 can protrude to be plugged into the mother board.

Accordingly, the heat spreader 10 of the memory module 1 according to the present invention, spreads the heat more evenly and at the same time shields the memory module 1 from electromagnetic interference. This is achieved by connecting the heat spreader 10 to the integrated components 6A, 6B each having two matched integrated capacitors 12A, 12B which are shown in FIG. 3. The second plates 14A, 14B of these capacitors 12A, 12B are each connected to a constant potential, i.e. the first plate 14A of capacitor 12A to a first supply voltage VSS and the second plate 14B of capacitor 12B to a second supply voltage VDD. In an embodiment, the supply voltages V_{SS}, V_{DD} are the supply voltages of the memory chips 2 mounted on the printed circuit board 3. The provision of integrated components 6A, 6B reduce the necessary number of decoupling capacitors while improving performance, i.e. by improving both common and differential mode noise suppression for high-frequency filtering.

In a preferred embodiment, the two matched capacitors 12A, 12B have an identical capacitance of some nF. The integrated components 6A, 6B may be mounted to the printed circuit board 3 as shown in FIG. 3 or in an alternative embodiment directly to the heat spreader 10.

Although modifications and changes may be suggested by those skilled in the art, it is the intention of the inventor to embody within the patent warranted hereon all changes and modifications as reasonably and properly come within the scope of his contribution to the art.

1. An apparatus for shielding of electromagnetic interference of a memory module comprising:
a heat spreader enclosing at least partially said memory module,
wherein said heat spreader is connected to at least one floating gate which is provided between first plates of matched integrated capacitors,
wherein second plates of said matched integrated capacitors each have a constant potential.

2. The apparatus according to claim 1,
wherein said at least one floating gate is provided between first plates of a first matched integrated capacitor and of a second matched integrated capacitor.

3. The apparatus according to claim 2,
wherein the second plate of the first matched integrated capacitor is connected to a first supply voltage of said memory module and
wherein the second plate of the second matched integrated capacitor is connected to a second supply voltage of said memory module.

4. The apparatus according to claim 1,
wherein said memory module is a dual in-line memory module.

5. The apparatus according to claim 1,
wherein said heat spreader surrounds said memory module.

6. The apparatus according to claim 1,
wherein the heat spreader consists of a material which is electrically and thermally conductive.

7. The apparatus according to claim 1,
wherein two matched capacitors are respectively integrated into one integrated component.

8. The apparatus according to claim 7,
wherein the integrated component is mounted on a printed circuit board of said memory module.

9. The apparatus according to claim 7,
wherein two matched capacitors which are integrated into one integrated component comprise the same capacity.

10. The apparatus according to claim 1,
wherein the memory module comprises memory chips mounted on at least one side of a printed circuit board of said memory module.

11. The apparatus according to claim 10,
wherein said memory module comprises a command and address buffer chip for buffering command and address signals received from a main printed circuit board.

12. The apparatus according to claim 11,
wherein the memory chips are arranged symmetrically to the command and address buffer chip located in a center position of said memory module.

13. The apparatus according to claim 12,
wherein said heat spreader spreads heat generated in the center of said memory module to the periphery of said memory module.

14. A memory module comprising:
a heat spreader surrounding a printed circuit board on which memory chips are mounted,
said heat spreader being connected to a floating gate of at least one integrated component comprising matched capacitors,
wherein said floating gate is provided between first plates of said matched capacitors and second plates of said matched capacitors,
wherein each second plate of said matched capacitors comprises a constant potential.

15. The memory module according to claim 14,
wherein said memory module is a dual in-line memory module comprising memory chips on both sides of said printed circuit board.

16. The memory module according to claim 14,
wherein said memory module is a single in-line memory module comprising memory chips on one side of said printed circuit board.

17. The memory module according to claim 14,
wherein said integrated component comprises two matched capacitors.

18. The memory module according to claim 17,
wherein the second plate of a first capacitor of said integrated component is connected to a negative supply voltage of said memory chips and
wherein the second plate of a second capacitor of said integrated component is connected to a positive supply voltage of said memory chips.

19. An electromagnetic shielding of a memory module comprising:
a housing enclosing at least partially said memory module; and
at least one integrated component connected to said housing said integrated component having at least one floating gate which is provided between first plates of matched capacitors integrated in said integrated component and having second plates to which a constant voltage is applied.

20. The electromagnetic shielding according to claim 19,
wherein said housing is a heat spreader.

21. A method for shielding electromagnetic interference of a memory module,
wherein a noise current induced in a heat spreader surrounding said memory module is conducted to at least one floating gate provided between first plates of matched capacitors,
wherein to each second plate of said matched capacitors a constant voltage is applied.
